(19) United States
(12) Patent Application Publication
(10) Pub. No.: US 2023/0140131 A1
(43) Pub. Date: May 4, 2023

(54) DUAL-DETECTOR REAL-TIME SPECTRUM ANALYZER

(71) Applicant: Keysight Technologies, Inc., Santa Rosa, CA (US)

(72) Inventors: Matthew S. Holcomb, Colorado Springs, CO (US); Paul Holcomb, Colorado Springs, CO (US); Connor P. McKay, Colorado Springs, CO (US)

(21) Appl. No.: 17/878,231

(22) Filed: Aug. 1, 2022

Related U.S. Application Data
(60) Provisional application No. 63/273,203, filed on Oct. 29, 2021.

(51) Int. Cl. G01R 23/16; G01R 13/02; H03M 1/12

(52) U.S. Cl. CPC G01R 23/16; G01R 13/0218; H03M 1/12

(57) ABSTRACT

A real-time spectrum analyzer (RSTA) includes an analog-to-digital converter (ADC) configured to convert in an input analog signal into a digital input data stream, a fast Fourier transform (FFT) unit configured to generate FFTs of the digital input data stream for successive time slices of the input analog signal, wherein the FFTs of each time slice are grouped into FFT bins, each FFT bin including the FFTs of a given frequency band, a first detector configured to reduce a number of FFTs per bin generated by the FFT unit and output a corresponding thinned FFT data stream for each of the successive time slices, a second detector configured to compress the thinned FFT data stream output by the first detector and output a compressed FFT data stream for each of the successive time slices, an FFT plotter configured to generate first display data representing an FFT plot of a given time slice of the input analog signal from the thinned FFT data stream output by the first detector, and a spectrogram plotter configured to generate second display data of a spectrogram of the given time slice and previous time slices of the input analog signal from the compressed FFT data stream output by the second detector.

### CROSS-REFERENCE TO RELATED APPLICATIONS

The present application claims priority under 35 U.S.C. § 119(e) to U.S. Provisional Application No. 63/273,203 filed on Oct. 29, 2021. The entire disclosure of U.S. Provisional Application No. 63/273,203 is specifically incorporated herein by reference in its entirety.

### BACKGROUND

When an oscilloscope is in real-time-spectrum-analysis (RTSA) mode, it continuously captures samples of a measured waveform. A plotter then periodically reads these samples and plots frequency domain representations of the signal to a screen of the oscilloscope. Typically, these periodic reads are synced to the video frame rate of the oscilloscope scope. The frequency domain representations may be a fast Fourier transform (FFT) plot and/or a spectrogram of the measured waveform.

### SUMMARY

According to an aspect of the inventive concepts, a real-time spectrum analyzer (RSTA) is provided that includes an analog-to-digital converter (ADC) configured to convert in an input analog signal into a digital input data stream, a fast Fourier transform (FFT) unit configured to generate FFTs of the digital input data stream for successive first time slices of the input analog signal, wherein each FFT includes a plurality of frequency bins for respective frequency bands of the input analog signal, and each frequency bin contains a value denoting an amplitude of the input analog signal at a frequency band of the bin during a given time slice of the input analog signal. The RTSA further includes a first detector configured to reduce a number of FFTs per unit time generated by the FFT unit and output a corresponding thinned FFT data stream including FFTs for each of successive second time slices, each of the second time slices being longer than each of the first time slices, and a second detector configured to reduce a number of FFTs per unit time output by the first detector and output a corresponding compressed FFT data stream including FFTs for each of successive third time slices, each of the third time slices being longer than each of the second time slices. The RTSA further includes an FFT plotter configured to generate first display data for the display representing an FFT plot of the input analog signal from the thinned FFT data stream output by the first detector, and a spectrogram plotter configured to generate second display data for the display of a spectrogram of the input analog signal from the compressed FFT data stream output by the second detector.

The first detector may reduce the number of FFTs per unit time to an input processing capacity of the FFT plotter.

A compression ratio of the second detector may be set in accordance with an input processing capacity of the spectrogram plotter.

The RSTA may further include a memory buffer storing the FFTs of the thinned FFT data stream, and outputting the stored FFTs to the FFT plotter and the second detector.

The RTSA may be implemented as an application-specific-integrated-circuit (ASIC) or field-programmable gate array (FPGA).

According to another aspect of the inventive concepts, a test instrument is provided that includes a real-time spectrum analyzer (RTSA) and a display. The RTSA includes an analog-to-digital converter (ADC) configured to convert an input analog signal into a digital input data stream, and a fast Fourier transform (FFT) unit configured to generate FFTs of the digital input data stream for successive first time slices of the input analog signal, wherein each FFT includes a plurality of frequency bins for respective frequency bands of the input analog signal, and each frequency bin contains a value denoting an amplitude of the input analog signal at a frequency band of the bin during a given time slice of the input analog signal. The RTSA further includes a first detector configured to reduce a number of FFTs per unit time generated by the FFT unit and output a corresponding thinned FFT data stream including FFTs for each of successive second time slices, each of the second time slices being longer than each of the first time slices, and a second detector configured to reduce a number of FFTs per unit time output by the first detector and output a corresponding compressed FFT data stream including FFTs for each of successive third time slices, each of the third time slices being longer than each of the second time slices. The RTSA further includes an FFT plotter configured to generate first display data for the display representing an FFT plot of the input analog signal from the thinned FFT data stream output by the first detector, and a spectrogram plotter configured to generate second display data for the display of a spectrogram of the input analog signal from the compressed FFT data stream output by the second detector.

The test instrument may be an oscilloscope, and the RTSA may be implemented as an application-specific-integrated-circuit (ASIC) or field-programmable gate array (FPGA) within the oscilloscope.

The first detector may reduce the number of FFTs per unit time to an input processing capacity of the FFT plotter.

A compression ratio of the second detector may be set in accordance with an input processing capacity of the spectrogram plotter.

The RSTA may further include a memory buffer storing the FFTs of the thinned FFT data stream, and outputting the stored FFTs to the FFT plotter and the second detector.

### BRIEF DESCRIPTION OF THE DRAWINGS

The above and other aspects and features of the inventive concepts will become readily apparent from the detailed description that follows, with reference to the accompanying drawings, in which:

FIG. 1 is a circuit block diagram of a test instrument in accordance with embodiments of the inventive concepts;

FIG. 2 is a perspective view of an oscilloscope in accordance with embodiments of the inventive concepts;

FIG. 3 is a simplified circuit block diagram of a real-time-spectrum-analyzer (RTSA) for generating fast Fourier transform (FFT) plots in accordance with the related art;

FIG. 4 is a simplified circuit block diagram of a real-time-spectrum-analyzer (RTSA) for generating spectrograms in accordance with the related art;

FIG. 5 is a simplified circuit block diagram of a real-time-spectrum-analyzer (RTSA) for generating both FFT plots and spectrograms in accordance with the related art;

FIG. 6 a simplified circuit block diagram of a real-time-spectrum-analyzer (RTSA) for generating both FFT plots and spectrograms in accordance with the embodiments of the inventive concepts; and

FIG. 7 a simplified circuit block diagram of a real-time-spectrum-analyzer (RTSA), including a buffer memory, for generating both FFT plots and spectrograms in accordance with the embodiments of the inventive concepts.

### DETAILED DESCRIPTION

Throughout the drawings, like reference numbers are given to like elements in the various embodiments. In addition, as the discussion below progresses from one embodiment to the next, a detailed description of already described elements common to previous embodiments is not repeated to avoid redundancy.

As is traditional in the field of the present disclosure, embodiments may be described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

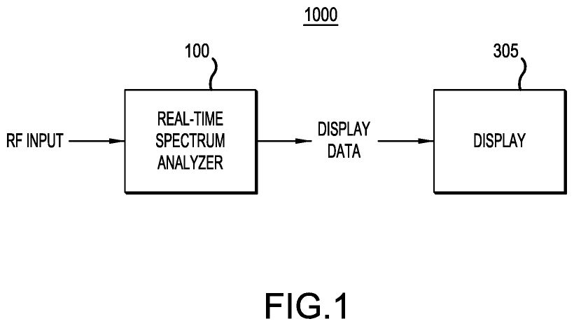

FIG. 1 is a block diagram of a measurement instrument 1000 in accordance with embodiments of the inventive concepts. The measurement instrument 1000 may, for example, be an oscilloscope.

Referring to FIG. 1, the measurement instrument 1000 includes a real-time-spectrum-analyzer (RTSA) 100 and a display 305. The RSTA 100 processes an input signal (e.g., a radio frequency (RF) signal) and transmits resulting display data in the form of an output data stream to the display 305. Generally, the RSTA 100 converts the input RF signal from a time domain to a frequency domain, and the output data stream of the RTSA 100 is a representation of the RF input signal in the frequency domain. This frequency domain representation may be a fast Fourier transform (FFT) plot and/or spectrogram of the RF input signal, and may be displayed on the display 305 or otherwise analyzed. The RTSA 100 may be implemented as an application-specific-integrated-circuit (ASIC) or field-programmable gate array (FPGA) of the measurement instrument 1000.

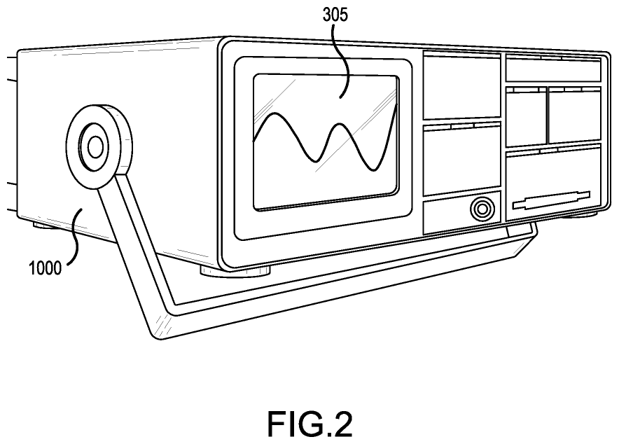

FIG. 2 is an exemplary perspective view of an oscilloscope which may constitute the measurement instrument 1000 of FIG. 1. During a typical operation of the oscilloscope 1000, a user applies an RF signal of a device or system under test (not shown) to an input port of the oscilloscope 1000. As one example, an output of the device or system under test may be coupled to an RF input of the oscilloscope, and the oscilloscope may then convert a signal at the output of the device or system under test to a waveform to be displayed on a display 305 of the oscilloscope 1000. As another example, a probe tip of an oscilloscope probe (not shown) may be placed in contact with a test point of the device or system under test. Upon contacting the test point, the probe detects a signal at the test point and transmits the signal to the oscilloscope 1000. The oscilloscope then converts the signal into a waveform to be displayed on a display 305 of the oscilloscope 1000.

In addition to the RTSA 100 which is the focus of the present disclosure, the oscilloscope 1000 may include a variety of other internal circuit components, input ports, output ports, control knobs, and display screens. Examples of internal circuit components include amplifiers, overdrive protection circuits, analog-to-digital converters, clamping circuits, frequency mixers, signal processors, volatile and nonvolatile memory, and so on.

As mentioned above, the displayed frequency domain representation input signal may be a fast Fourier transform (FFT) plot and/or spectrogram. An FFT plot is typically displayed as a two-dimensional graph in which the x-axis denotes different frequency bands of the input RF signal, and the y-axis denotes an power (or energy) level within each of the frequency bands. The power level may be a maximum power within each band, an average power within each band, and so on. A spectrogram, on the other hand, is generally characterized by the presentation of power values at different frequency bands for successive units or slices of time. In other words, a third dimension is included which depicts a history of the RF signal behavior in the frequency domain. The presentation can visually take different forms. For example, the spectrogram may be in the form of a three-dimensional graph with an x-axis denoting frequency (or frequency bands), a y-axis denoting time (or time slices), and a z-axis denoting signal power. As another example, the spectrogram may take the form of a two-dimensional graph in which color variations used to represent power (or amplitude). Other formats are known as well. Regardless of the format of the graphical representation of the spectrogram, there are successive time slices, and within each time slice, there is an power or energy level at each of different frequency bands within a range of frequency bands, The frequency bands and intensities are derived from data that was acquired or processed within one time slice. A common choice for the duration of the time slice is one video frame of the instrument displaying the spectrogram. So, for example, in case where a video frame is 1/60^{th} of a second, the spectrogram may be updated with data of a new time slice 60 times a second. In this example, assuming 10 seconds of frequency domain history are displayed, then FFT power values for 600 time slices would be displayed simultaneously.

Generally, the amount of FFTs that can be simultaneously plotted on a display of an oscilloscope is limited to a given maximum determined by a number of factors such as the size of the video memory and so on. In the meantime, as described above, the FFT plot depicts FFTs of an input signal for a given time slice, whereas the spectrogram additionally displays a history of FFTs of the input signal of previous time slices. In other words, the spectrogram spreads out the displayable FFT information over many time slices, while the FFT plot confines the displayable FFT information to that of a single time slice. As such, the updated FFTs of each video frame of the FFT plot can correspond to or approach the display maximum. On the other hand, since a history of FFTs is also displayed in a spectrogram, the updated number of FFTs of each video frame of the spectrogram is far less than the display maximum.

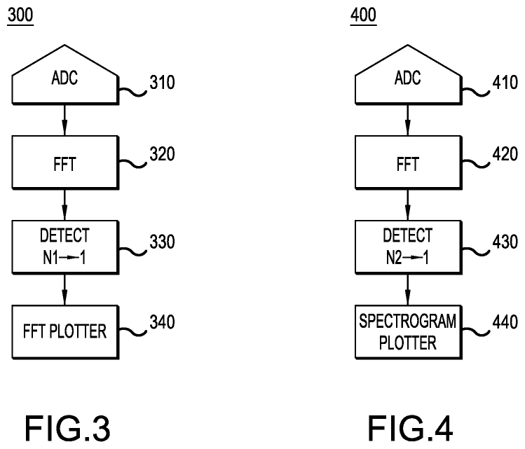

FIGS. 3 and 4 depict simplified circuit diagrams of a real-time spectrum analyzer (RTSA) 300 for generating an FFT plot on an oscilloscope display, and an RTSA 400 for generating a spectrogram on an oscilloscope display, respectfully.

Referring first to FIG. 3, the RTSA 300 for generating an FFT plot includes an analog-to-digital conversion circuit 310, an FFT circuit 320, a detector 330 and an FFT plotter 340.

In operation, the ADC circuit 310 is configured to convert an input RF signal into a digital input data stream. The input data stream essentially consist of time-domain samples of the input RF signal, and these samples are supplied to the FFT circuit 320. Although not shown, a digital down converter (DDC) may be provided at the output of the ADC circuit 310 to convert digital data stream to a lower frequency digital signal having a lower sampling rate in order to simplify subsequent processing stages. In addition, although also not shown, a memory may be provided to store the data samples prior to application to the FFT circuit 320. The FFT circuit 320 is configured to compute the FFTs of the input RF signal from the time-domain samples captured using the ADC circuit 310. As one skilled in the art will understand, the FFTs represent a frequency domain of the input RF signal at each of successive time slices of the input signal. That is, each FFT denotes a power (or amplitude) of the input RF signal at a given portion of a given frequency spectrum. More specifically, each FFT contains a given number of frequency bins, and each bin contains a value that denotes a power (or amplitude) at a frequency band of the bin. As one non-limiting example, each FFT may contain 2048 bins (which may be referred to as a 2048 point FFT). Assuming an example in which 100 Hz bandwidth input signal is processed with a 2048 point FFT, each bin would represent the power of the input signal from a 100 Hz/2048≈0.05 Hz frequency slice (or band) at a given time slice of the input signal.

The detector 330 is configured to reduce the number of FFTs output by the FFT circuit 320 to an input processing capacity of the FFT plotter 340. That is, the detector 330 may combine multiple FFTs of successive time slices to produce a frequency spectrum that represents a larger time range than that of the individual time slices. In this manner, the overall number of FFTs is reduced. For example, each set of N1 FFTs may be reduced (“thinned”) to a single FFT, where N1 is an integer of at least one. This thinning process is referenced in FIG. 3 as “N1→1”. Note that in the case where N1=1, the detector 330 passes through all the FFTs to be updated in a video frame by the FFT plotter 340.

The plotter 340 is configured to generate corresponding display data of the frequency domain representation of the input RF signal from the FFTs supplied via the detector 330. As explained previously, the FFTs are updated each video frame.

The RTSA 400 of the related art of FIG. 4 for generating the spectrogram is similarly configured. That is, the RTSA 400 includes an analog-to-digital conversion circuit 410, an FFT circuit 420, a detector 430 and an FFT plotter 440.

In operation, the ADC circuit 410 is configured to convert an input RF signal into a digital input data stream. The input data stream essentially consist of time-domain samples of the input RF signal, and these samples are supplied to the FFT circuit 420. Although not shown, a digital down converter (DDC) may be provided at the output of the ADC circuit 410 to convert digital data stream to a lower frequency digital signal having a lower sampling rate in order to simplify subsequent processing stages. In addition, although also not shown, a memory may be provided to store the data samples prior to application to the FFT circuit 420. The FFT circuit 420 is configured to compute the FFTs of the input RF signal from the time-domain samples captured using the ADC circuit 410. As discussed above, each FFT contains a number of frequency bins which represent an amplitude of the input RF signal at a given portion of a given frequency spectrum during a given time slice of the input signal.

The detector 430 is configured to compress the number of FFTs output by the FFT circuit 420 to an input processing capacity of the spectrogram plotter 440. That is, the detector 430 may combine multiple FFTs of successive time slices to produce a frequency spectrum that represents a larger time range than that of the individual time slices. In this manner, the overall number of FFTs is reduced. This compression process is referenced in FIG. 4 as “N2→1”. To put the degree of compression into context, N2 may be on the order of 10,000 or more. This is because, as explained previously, far less displayed data (FFTs) is updated in each video frame of the spectrogram when compared to the FFT plot.

The spectrogram plotter 440 is configured to generate corresponding display data of the spectrogram representation of the input RF signal from the FFTs supplied via the detector 430.

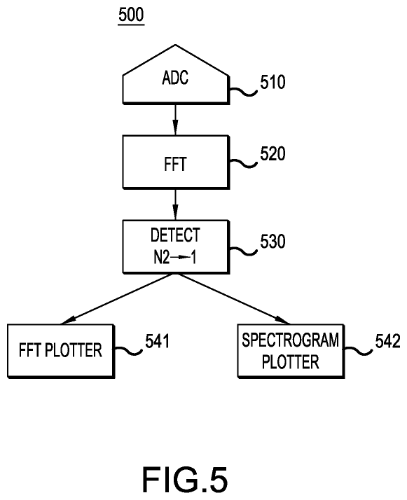

It may be desirable to have the oscilloscope display both an FFT plot and a spectrogram of the measured signal. FIG. 5 is a simplified circuit diagram of a traditional RTSA 500 configured to generate both an FFT plot and a spectrogram of a measured signal.

Referring to FIG. 5, the RSTA includes an analog-to-digital conversion circuit 510, an FFT circuit 520, a detector 530, an FFT plotter 541 and a spectrogram plotter 542.

In operation, the ADC circuit 510 is configured to convert an input RF signal into a digital input data stream. The input data stream essentially consist of time-domain samples of the input RF signal, and these samples are supplied to the FFT circuit 520. Although not shown, a digital down converter (DDC) may be provided at the output of the ADC circuit 510 to convert digital data stream to a lower frequency digital signal having a lower sampling rate in order to simplify subsequent processing stages. In addition, although also not shown, a memory may be provided to store the data samples prior to application to the FFT circuit 520. The FFT circuit 520 is configured to compute the FFTs of the input RF signal from the time-domain samples captured using the ADC circuit 410. As before, each FFT contains a number of frequency bins which represent an amplitude of the input RF signal at a given portion of a given frequency spectrum during a given time slice of the input signal.

The detector 530 is configured to compress the number of FFTs output by the FFT circuit 520 to an input processing capacity of the spectrogram plotter 542. That is, the detector 530 may combine multiple FFTs of successive time slices to produce a frequency spectrum that represents a larger time range than that of the individual time slices. For example, each set of N2 FFTs may be compressed to a single FFT, where N2 is an integer greater than one. As in FIG. 4, this compression process is referenced in FIG. 5 as “N2→1”. Again, to put the degree of compression into context, N2 may be on the order of 10,000 or more. This is because, as explained previously, far less displayed data (FFTs) is updated in each video frame of the spectrogram. The spectrogram plotter 542 is configured to generate corresponding display data of the spectrogram representation of the input RF signal from the FFTs supplied via the detector 530. Likewise, the FFT plotter 541 is configured to generate corresponding display data of an FFT plot representation of the input RF signal from the compressed FFTs supplied via the detector 530.

While the configuration of FIG. 5 conveniently generates an FFT plot from the same FFTs used to generate the spectrogram, it suffers a disadvantage in that much of the information from each FFT is lost when displaying the FFT plot, i.e., only a relatively few (1 of N2) FFTs make it to the display screen.

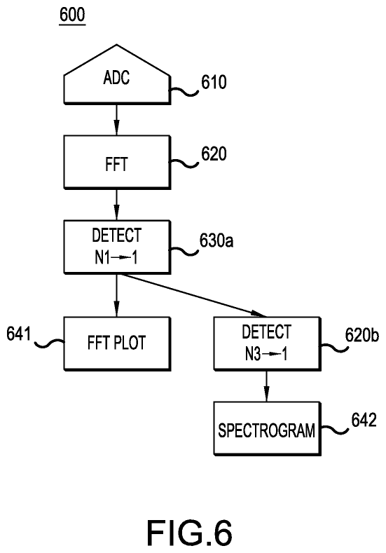

FIG. 6 a simplified circuit block diagram of a real-time-spectrum-analyzer (RTSA) 600 for generating both an FFT plot and a spectrogram in accordance with the embodiments of the inventive concepts.

As shown in FIG. 6, the RTSA 600 includes an analog-to-digital conversion circuit 610, an FFT circuit 620, a first detector 630a, an FFT plotter 641, a second detector 630b and a spectrogram plotter 642.

In operation, the ADC circuit 610 is configured to convert an input RF signal into a digital input data stream. The input data stream essentially consist of time-domain samples of the input RF signal, and these samples are supplied to the FFT circuit 620. Although not shown, a digital down converter (DDC) may be provided at the output of the ADC circuit 610 to convert digital data stream to a lower frequency digital signal having a lower sampling rate in order to simplify subsequent processing stages. In addition, although also not shown, a memory may be provided to store the data samples prior to application to the FFT circuit 620.

The FFT circuit 620 is configured to compute the FFTs of the input RF signal from the time-domain samples captured using the ADC circuit 610. As before, each FFT contains a number of frequency bins which represent an amplitude of the input RF signal at a given portion of a given frequency spectrum during a given time slice of the input signal.

The first detector 630a is configured to reduce the number of FFTs output by the FFT circuit 620 to an input processing capacity of the FFT plotter 640. That is, for example, the detector 630a may combine multiple FFTs of successive time slices to produce a frequency spectrum that represents a larger time range than that of the individual time slices. Each set of N1 FFTs may be reduced (“thinned”) to a single FFT, where N1 is an integer of at least one. As a result, each FFT of the thinned data will denote the frequency domain across N1 time slices of the original FFT data. This thinning process is referenced in FIG. 6 as “N1→1”. Note that in the case where N1=1, the detector 630a passes through all the FFTs to be updated in each video frame by the FFT plotter 641.

The FFT plotter 641 is configured to generate corresponding display data of the frequency domain representation of the input RF signal from the FFTs supplied via the first detector 630a. As explained previously, the FFTs are updated each video frame.

In addition, the “thinned” FFTs output by the first detector 630b are applied to the second detector 630b. The second detector 630b is configured to compress the number of FFTs output by the first detector 630a to an input processing capacity of the spectrogram plotter 642. That is, for example, the detector 630b may combine multiple FFTs of successive time slices to produce a frequency spectrum that represents a larger time range than that of the individual time slices (as thinned by the detector 630a). Each set of N1 FFTs may be reduced (“thinned”) to a single FFT, where N2 is an integer of at least one. For example, each set of N3 FFTs from the first detector 630a may be compressed to a single FFT, where N3 is an integer greater than one. As a result, each FFT of the compressed data will denote the frequency domain across N1*N3 time slices of the original FFT data. This compression process is referenced in FIG. 5 as “N3→1”. Once again, to put the degree of compression into context, the thinning (N1) of the first detector 630a and compression (N3) of the second detector 630b combined may be on the order of 10,000 or more. This is because, as explained previously, far less displayed data (FFTs) is updated in each video frame of the spectrogram as compared to each video frame of the FFT plot.

The spectrogram plotter 642 is configured to generate corresponding display data of the spectrogram representation of the input RF signal from the FFTs supplied via the second detector 630b.

Referring back to FIG. 3, for plotting FFT's, a detector is introduced to thin or compress N1 FFT's down to one. This thinned record outputs 1 FFT for every N1 inputs. Compression could be the max per bin, the min per bin, the average per bin, the first of every N1, a randomly chosen 1 of every N1, and so on. The detector is used to reduce the input FFT rate (often quite fast) down to a rate which the FFT plotter can process. (As an aside, the detector may also be used to distill the input records down to what is of interest to the user.) A similar topology as in FIG. 4 is used for plotting spectrograms. Here, however, the display “rolls” vertically at a much slower rate (perhaps a few pixels per video frame), so a much longer detection interval (N2) is used (N1<<N2).

In the meantime, when simultaneously displaying both an FFT plot and a spectrogram, the traditional RTSA topology of FIG. 5 entails combining many FFT records together (N2→1) to form a single display line on the spectrogram, and a corresponding single trace on the FFT display. This results in a loss of information of the statistical nature of the FFT distribution for the FFT plot. As one example, when using a ‘max hold’ detection algorithm for compression, the maximum of input records would be displayed. However, it is unknown whether all inputs are at or near this maximum, or instead whether there a single rogue input well above the others which resulted in the maximum. This information has been lost when compression the FFTs to “fit” the spectrogram.

The new RTSA topology of embodiments of the inventive concepts as in FIG. 6 introduces a second detector which allows for all of the input FFT records to be displayed simultaneously, while as the same time the spectrogram can be generated as before. The first detector is used to “thin” the incoming data down to the rate which the FFT plotter can accept, and the second detector then compresses the data down to the rate of the spectrogram. As one example, by not limiting the rate to the FFT plotter, the FFT plot is able to provide statistical distribution of the input given by the brightness of the traces, simultaneously with the desired spectrogram.

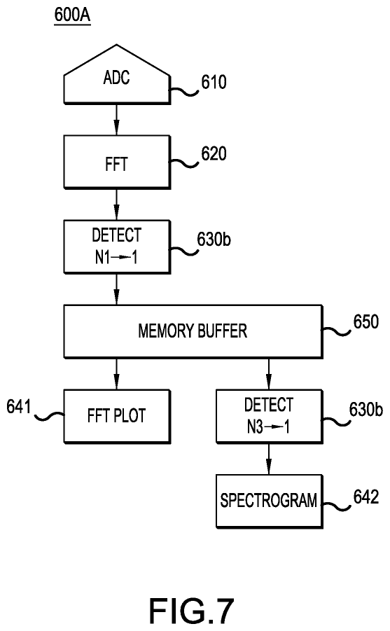

FIG. 7 depicts an RTSA 600A according to another embodiment of the inventive concepts in which a buffer memory 650 is added at the output of the first detector 630a. The buffer memory 650 is configured to temporarily store (buffer) the thinned FFT data stream from the first detector 630a, and then supply the stored FFTs to the FFT plotter 641 and second detector 630b. Otherwise, the embodiment of FIG. 7 is the same as that of FIG. 6, and a further detailed description is omitted here to avoid redundancy.

While the disclosure references exemplary embodiments, it will be apparent to those skilled in the art that various changes and modifications may be made without departing from the spirit and scope of the present teachings. Therefore, it should be understood that the above embodiments are not limiting, but illustrative.

What is claimed is:

1. A real-time spectrum analyzer (RSTA), comprising:
analog-to-digital converter (ADC) configured to convert an input analog signal into a digital input data stream;
a fast Fourier transform (FFT) unit configured to generate FFTs of the digital input data stream for successive first time slices of the input analog signal, wherein each FFT includes a plurality of frequency bins for respective frequency bands of the input analog signal, and each frequency bin contains a value denoting an amplitude of the input analog signal at a frequency band of the bin during a given time slice of the input analog signal;
a first detector configured to reduce a number of FFTs per unit time generated by the FFT unit and output a corresponding thinned FFT data stream including FFTs for each of successive second time slices, each of the second time slices being longer than each of the first time slices;
a second detector configured to reduce a number of FFTs per unit time output by the first detector and output a corresponding compressed FFT data stream including FFTs for each of successive third time slices, each of the third time slices being longer than each of the second time slices;
an FFT plotter configured to generate first display data representing an FFT plot of the input analog signal from the thinned FFT data stream output by the first detector; and
a spectrogram plotter configured to generate second display data of a spectrogram of the input analog signal from the compressed FFT data stream output by the second detector.

2. The RSTA of claim 1, wherein the first detector reduces the number of FFTs per unit time to an input processing capacity of the FFT plotter.

3. The RSTA of claim 1, wherein a compression ratio of the second detector is set in accordance with an input processing capacity of the spectrogram plotter.

4. The RSTA of claim 1, further comprising a memory buffer storing the FFTs of the thinned FFT data stream, and outputting the stored FFTs to the FFT plotter and the second detector.

5. The RSTA of claim 1, wherein the RTSA is implemented as an application-specific-integrated-circuit (ASIC) or field-programmable gate array (FPGA).

6. A test instrument, comprising a real-time spectrum analyzer (RTSA) and a display, wherein the RTSA comprises:
analog-to-digital converter (ADC) configured to convert in an input analog signal into a digital input data stream;
a fast Fourier transform (FFT) unit configured to generate FFTs of the digital input data stream for successive first time slices of the input analog signal, wherein each FFT includes a plurality of frequency bins for respective frequency bands of the input analog signal, and each frequency bin contains a value denoting an amplitude of the input analog signal at a frequency band of the bin during a given time slice of the input analog signal;
a first detector configured to reduce a number of FFTs per unit time generated by the FFT unit and output a corresponding thinned FFT data stream including FFTs for each of successive second time slices, each of the second time slices being longer than each of the first time slices;
a second detector configured to reduce a number of FFTs per unit time output by the first detector and output a corresponding compressed FFT data stream including FFTs for each of successive third time slices, each of the third time slices being longer than each of the second time slices;
an FFT plotter configured to generate first display data for the display representing an FFT plot of the input analog signal from the thinned FFT data stream output by the first detector; and
a spectrogram plotter configured to generate second display data for the display of a spectrogram of the input analog signal from the compressed FFT data stream output by the second detector.

7. The test instrument of claim 6, wherein the test instrument is an oscilloscope.

8. The test instrument of claim 7, wherein the RTSA is implemented as an application-specific-integrated-circuit (ASIC) or field-programmable gate array (FPGA) within the oscilloscope.

9. The RSTA of claim 7, wherein the first detector reduces the number of FFTs per unit time to an input processing capacity of the FFT plotter.

10. The RSTA of claim 9, wherein a compression ratio of the second detector is set in accordance with an input processing capacity of the spectrogram plotter.

11. The RSTA of claim 10, further comprising a memory buffer storing the FFTs of the thinned FFT data stream, and outputting the stored FFTs to the FFT plotter and the second detector.
